(19) United States
(12) Patent Application Publication
(10) Pub. No.: US 2018/0160568 A1
(43) Pub. Date: Jun. 7, 2018

(54) DEVICE AND METHOD FOR REMOVING MOISTURE FROM A SWITCH CABINET

(71) Applicant: WIND & SUN TECHNOLOGIES S.L., VILADECANS (BARCELONA) (ES)

(72) Inventor: LORENZ FEDDERSEN, FLENSBURG (DE)

(21) Appl. No.: 15/735,029

(22) PCT Filed: Jun. 8, 2015
(86) PCT No.: PCT/EP2015/062700

§ 371 Date: Dec. 8, 2017

(51) Int. Cl. H05K 7/20; H05K 5/02; H02G 3/08; H02G 3/03; G05D 22/02

(52) U.S. Cl. CPC H05K 7/20381; H05K 5/0213; H05K 7/2039; H05K 7/20136; G05D 22/02; H05K 7/20145; H02G 3/088; H02G 3/03; H05K 7/20318

(57) ABSTRACT

The invention relates to a device for removing moisture from a switch cabinet, comprising at least one Peltier element, which can be connected to a direct-voltage source, a condensation body, which is connected to a cooling side of the Peltier element in a thermally conductive manner and which can be cooled when current flows through the Peltier element, an electronic control circuit for controlling the current flow through the Peltier element, and an apparatus for removing moisture condensed on the condensation element from the interior into the surroundings of the switch cabinet, wherein the control apparatus is designed to temporarily reverse the polarity of the current supply of the Peltier element.

The present invention relates to a device for removing moisture from a switch cabinet, comprising at least one Peltier element, which can be connected to a direct current voltage source, a condensation body, which is connected to a cooling side of the Peltier element in a thermally conductive manner which can be cooled when current flows through the Peltier element, an electronic control circuit for controlling the current flow through the Peltier element, and an apparatus for conveying moisture condensed on the condensation element from the interior to the surroundings of the switch cabinet. The invention further relates to a corresponding method for removing moisture from a switch cabinet.

Relating to water- and dustproof switch cabinets, which are used in the outdoor area, the problem arises frequently that the switch cabinet cools down at night and the temperature falls below the dew point. Air moisture deposits as a condensate on the electrical components and the risk of an electrical flashover and of corrosion increases strongly. Caused by maintenance under damp weather condition additional moisture is brought into the switch cabinet. In general, the moisture brought into the switch cabinet can, based on its tightness, hardly discharge from the switch cabinet into the surrounding, also under warm weather condition.

In the state of the art it is known to arrange an electrical heating arrangement in the switch cabinet which is controlled so that undercutting the dew point is prevented in the switch cabinet. However, the energy consumption for the heating arrangement is considerable, in particular at outside temperatures below the freezing point.

From the DE 10 2009 008 233 A1 a class-forming device for removing moisture from a closed switch cabinet is known. To prevent the icing of the condensation element a regulation of the cooling temperature is provided on the basis of a signal of a temperature sensor, which is realized so that the temperature of the condensation element does not fall below the freezing point. Depending on the temperature conditions this can imply that the cooling performance of the condensation body is reduced to zero, which can reduce or even prevent the removing of moisture from the switch cabinet.

The object of the invention is to provide a device and a method, which achieve a reliable and cost-effective removal of moisture from a closed switch cabinet independent of the particular temperature condition.

The invention solves this object with the features of the independent claims. The polarity of the current supply of the Peltier element is temporarily switched to heat the heat sink and melt the ice which is formed on the heat sink and can preferably be conveyed from the interior of the switch cabinet to its surrounding via the condensate conduit. A completely maintenance-free and permanent operation of the switch cabinet is possible with the construction according to the invention. Opposite the state of the art, where problems arise, in particular at temperatures near and below the freezing point, the device according to the invention can be used at any temperature. An energy intensive separate heating apparatus for heating the interior of the switch cabinet in case of lower ambient temperatures is dispensable according to the invention, since the Peltier element, which is present anyway, is used as heating body to heat the condensation body by changing temporarily and selectively the polarity.

Preferably, the change of the polarity of the current supply of the Peltier element is caused by the detection of a freezing condition, for example dependent on the signal of a temperature sensor, which is adapted to measure a temperature corresponding to the temperature of the condensation element. In this case the detection of a freezing condition can advantageously require that the temperature measured with the temperature sensor falls below a predetermined temperature. It can be advantageous that changing the polarity is carried out after the expiry of a predetermined duration, preferably at least 10 minutes, more preferably at least 20 minutes, even more preferably at least 30 minutes, after falling below the predetermined temperature, since the icing cannot take place abruptly and the cooling operation can be maintained a while, which improves the cooling efficiency.

Alternative to the detection of a freezing condition, the change of the polarity can also be carried out time-controlled, in particular periodically. For example, during a cooling period cool the condensation body, change the polarity, during a heating period heat the condensation body, switch back the polarity, and so on. Here the cooling period preferably amounts to at least 30 minutes, advantageously at least 60 minutes, and is preferably longer than the heating period, preferably at least by a factor 5, more preferably at least by a factor 10.

Preferably, the heating side of the Peltier element is connected to a heat sink to convey the electric heat of the Peltier element away in order to not impair the cooling efficiency of the Peltier element. Preferably, not only the condensation body but also the heat sink is entirely arranged in the interior of the switch cabinet. In the state of the art the heat sink is usually at least partly arranged on the outer face of the switch cabinet to convey the heat produced by the Peltier element to the surrounding of the switch cabinet. However, this requires a corresponding opening in the casing of the switch cabinet that is costly to produce, which, for example, impedes the retrofitting of already existing switch cabinets. Additionally the invention has realized in so far that a conveying of the heat produced by the Peltier element to the surrounding of the switch cabinet is not necessarily desirable, since by reason of the corresponding lowering of the temperature in the interior of the switch cabinet the degree of efficiency of the removal of moisture decreases and the risk of icing increases.

In the following the invention shall be illustrated on the basis of preferred embodiments with reference to the accompanying drawing, wherein:

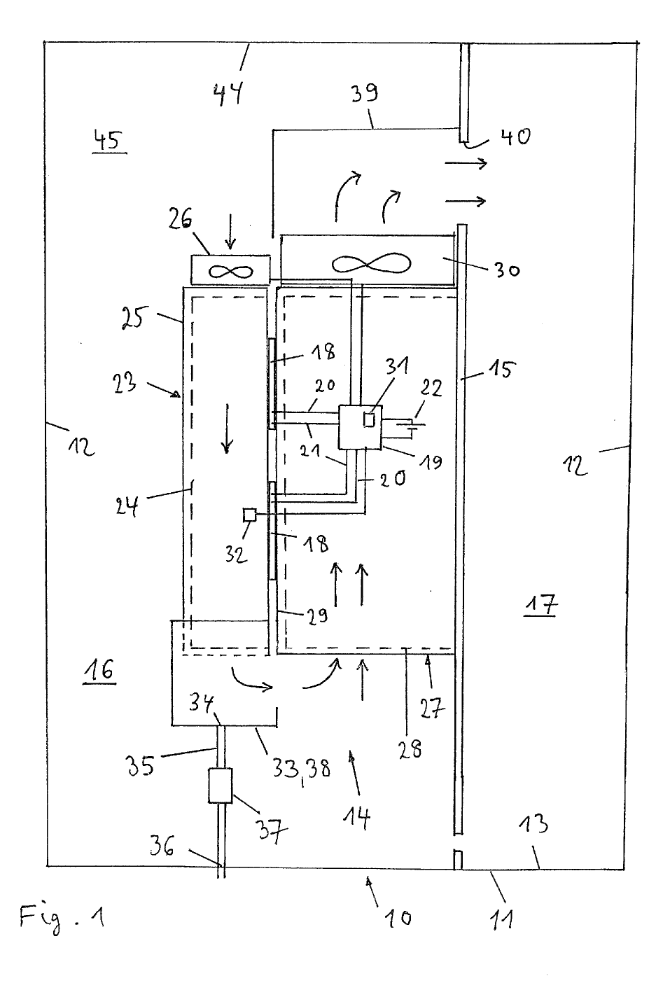

FIG. 1 shows a schematic side view of a switch cabinet with a device for removing moisture from the interior of the switch cabinet.

The closed switch cabinet 10 with the casing 11 which is shown only schematically in the FIGURE is dust protected at least according to class 5, preferably dust tight according to class 6 according to DIN EN 60529 and/or splash proof at least according to class 4, preferably hose proof at least according to class 5 according to DIN EN 60529, and provides for example the degree of protection IP65. A typical application is a switch cabinet in the outdoor area (outdoor—switch cabinet), for example for solar plants or wind energy plants. The casing 11 comprises in particular side walls 12, bottom wall 13, cover wall 44, back wall 45 and a front wall which is not shown in FIG. 1. Closed means essentially closed except functional openings, but not an air tight or pressure tight closed.

A device 14 for removing moisture from the switch cabinet 10 is arranged in the interior of the switch cabinet 10 respectively of the casing 11 of the switch cabinet. The device 14 is preferably retained on a vertical partition wall 15 which divides the interior into two domains 16, 17. The domain 16 contains the device and the domain 17 can for example contain electronics of the switch cabinet. The domain 17 can in particular have a larger volume than the domain 16. The device can alternatively be retained on any of the other walls 12, 13, 44, 45.

The device 14 for removing moisture comprises at least one Peltier element 18, here for example two Peltier elements 18, whereby each of the Peltier elements 18 is, via two wires 20, 21, connected with a control circuit 19, which is connected to a direct current voltage source 22 that is depicted only symbolically in FIG. 1. The direct current voltage source 22 is provided within the switch cabinet 10, whereby the electrical energy can in particular stem from an energy reservoir, a mains connection or another energy producing device. The Peltier element 18 is connected in a thermally conductive manner on the cooling side of the Peltier element 18 with a condensation body 23, whereby the thermally conductive connection can for example be mediated by means of a heat transfer paste.

The condensation body 23 preferably comprises a finned element 24 which comprises cooling fins. Furthermore, the condensation body 23 preferably comprises a both-sided open pipe body 25, preferably vertically oriented, surrounding the finned element 24. An electrical fan 26 is preferably provided to generate an airstream through the pipe body 25 along the finned element 24, in particular the electrical fan 26 is arranged at one of the two open ends, here the upper end, of the pipe body 25 and is controlled by the control circuit 19.

The Peltier element 18 is connected on its heating side with a heat sink 27 in a thermally conductive manner, whereby the thermally conductive connection can for example be mediated by means of a heat transfer paste. The heat sink 27 preferably comprises a finned element 28 which comprises cooling fins. Furthermore, the heat sink 27 preferably comprises a both-sided open pipe body 29, preferably parallel to the pipe body 25 and thereby preferably also vertically oriented, surrounding the finned element 28. An electrical fan 30 is preferably provided to generate an airstream through the pipe body 29 along the finned element 28, in particular the electrical fan 30 is arranged at one of the two open ends, here the upper end, of the pipe body 29 and is controlled by the control circuit 19.

The control circuit 19 is connected with a sensor 31 to measure the air moisture within the switch cabinet 10. The sensor 31 can be a part of the control circuit 19 or be arranged at any other suitable position within the switch cabinet 10 and be connected with the control circuit 19, for example via a signal cable. The control circuit 19 is furthermore connected with a temperature sensor 32, which can be mounted on the finned element 24 or on the pipe body 25, adapted to measure the temperature of the condensation body 23. Alternatively, it can also be a non-contacting temperature sensing device 32.

A condensate pan or a condensate funnel 33 to catch the fluid that is condensed on the condensation body 23 is arranged at the lower end of the condensation body 23. A discharge opening 34 is provided in the bottom of the condensate pan 33. A condensate conduit 35 connects the discharge opening 34 with a corresponding discharge opening 36, which empties into the surrounding of the switch cabinet 10, here in the ground 13. An insect filter 37 is interposed in the condensate conduit 35 in order to prevent insects from reaching the interior of the switch cabinet from the outside via the condensate conduit 35. Instead of the condensate conduit another apparatus 35 can be provided to discharge the moisture that is condensed on the condensation body 23 to the surrounding of the switch cabinet 10, for example a channel.

A conduit apparatus 38, which is here advantageously formed by the condensate pan 33, is preferably provided at the exhaust air side of the condensation body 23. The conduit apparatus 38 conducts the air that leaves the condensation body 23 to the air intake of the heat sink 27. The direct use of the air cooled in the condensation body 23 to cool the heat sink 27 increases the cooling efficiency and can lead to energy saving. The described air guidance is particularly facilitated by the opposite flow directions of the fans 26, 30 for the condensation body 23 and the heat sink 27, as illustrated in FIG. 1 by the arrows that indicate the air flow.

A conduit apparatus 39, which conducts the warm exhaust air that leaves the heat sink through an opening 40 in the partition wall 15 to the domain 17 of the switch cabinet, is preferably provided at the exhaust air side of the heat sink 27. This has the advantage that the warm exhaust air that leaves the heat sink needs to travel a possibly large distance before it can enter the condensation body 23, since warm and dry air can impede the cooling efficiency of the condensation body 23.

The heat sink 27 is preferably larger than the condensation body 23 and the fan 30 for the heat sink 27 has preferably larger power consumption than the fan 26 for the condensation body 23, since the heat sink 27 conducts the electrical power loss away in addition to the cooling power of the condensation body 23.

In the following the functioning of the device 14 shall be described in a preferred embodiment.

The air moisture in the interior of the switch cabinet 10 is monitored permanently by means of the air moisture sensor 31 of the control circuit 19. As long as the air moisture does not exceed a particular value, the device 14 is essentially standing idle, i.e., neither the Peltier elements 18 nor the fans 26, 30 are supplied with current.

As soon as the air moisture measured with the air moisture sensor 31 exceeds a particular value, for example as caused by the opening of the switch cabinet for maintenance or repair work, the control circuit 19 puts the Peltier elements 18 and the fans 26, 30 into operation in order to remove moisture from the air in the switch cabinet. Thereto the wires 20, 21 of the Peltier elements 18 are connected with the direct current voltage source 22 in such a manner that the side of the Peltier elements 18 that is connected to the condensation body 23 is cooled and the side of the Peltier elements 18 that is connected to the heat sink 27 is warmed. The condensation body 23 is cooled to a temperature of preferably at least 5 degrees, more preferably at least 10 degrees below the ambient air. The fans 26, 30 are operated so that the flow direction in the condensation body 23 is opposite the flow direction in the heat sink 27 as shown in FIG. 1. The air in the switch cabinet will be blown continuously through the condensation body 23 by means of the fan 26. The air in the switch cabinet will be cooled through the cold condensation boy 23. Upon falling below the dew point the water contained in the air in the switch cabinet condenses and deposits on the condensation body 23. The water runs down the condensation body 23, will be caught by the condensate pan 33 and will be conveyed via the condensate conduit 35 and the insect filter 37 to the surrounding. As long as the temperature of the condensation body 23 lies above zero ° C., the moisture removal device 14 can operate permanently. If the air moisture measured with the air moisture sensor 31 falls below a desired value for one time or for a particular duration, the Peltier elements 18 and, if necessary with a time delay, also the fans 26, 30 can be put out of order again.

If, however, the temperature of the condensation body 23 measured with the temperature sensor 32 drops below zero ° C., icing occurs and after a while the condensation body 23 would be covered with an ice film that reduces the cooling efficiency of the condensation body 23 dramatically. Reasoned by this, if the temperature of the condensation body 23 measured by the temperature sensor 32 falls below a defined value in the range near the freezing point a freezing condition is assessed by the control circuit 19. Icing can for example be detected if the temperature of the condensation body 23 lies below a predetermined temperature in a range or below the freezing point for a predetermined duration of at least 30 minutes, preferably at least 60 minutes.

Other freezing conditions are possible. In general, the freezing condition can depend on the time evolution of the temperature of the condensation body 23 measured with the temperature sensor 32. The freezing condition can also depend on the signal of the air moisture sensor 31. The signal of a temperature sensor, which is arranged at another position in the switch cabinet, could also be used in addition or alternatively to the temperature sensor 32. For example a temperature measured with a temperature sensor, which is arranged at the air intake of the heat sink 27 could be a measure for the freezing of the condensation body 23.

The control circuit 19 changes the polarity of the current supply of the Peltier elements 18 as a freezing condition is detected or after the expiry of a predefined duration of preferably at least 30 minutes, more preferably at least 60 minutes, after the freezing condition is detected. Thereto the wires 20, 21 of the Peltier elements 18 are connected to the direct current voltage source 22 opposite to the moisture removal process so that the side of the Peltier elements 18 connected to the condensation body 23 is heated and the side of the Peltier elements 18 connected to the heat sink 27 is cooled.

The ice which is deposited at the condensation body 23 will melt due to its warming and is conveyed via the condensate pan 33 and condensate conduit 35 to the surrounding.

After a defrosting condition is detected, for example after the expiry of a predefined time, or if the temperature measured with the temperature sensor 32 exceeds a particular value which lies above the predetermined temperature value for the freezing condition and in particular above zero ° C., the polarity of the current supply of the Peltier elements 18 can be changed again in order to go into the normal moisture removal process again.

Based on the described automatic defrosting function, a moisture removal from the air in the switch cabinet can also take place permanently and without any problems at temperatures around and below the freezing point.

1-15. (canceled)

16. A device for removing moisture from a switch cabinet, comprising:
a Peltier element,
wherein the Peltier element has a cooling side and a heating side,
wherein the Peltier element is configured to be connected to a direct current voltage source;
a condensation body,
wherein the condensation body is connected to the cooling side of the Peltier element in a thermally conductive manner;
an electronic control circuit,
wherein the electronic control circuit is connected to the Peltier element,
wherein the electronic control circuit is configured to:
(ii) connect to the direct current voltage source; and
(iii) control a Peltier supply current that flows from the direct current voltage source through the Peltier element, such that:
(a) when the Peltier supply current has a first polarity, the Peltier supply current flows through the Peltier element in a first direction, and the condensation body is cooled; and
(b) when the Peltier supply current has a second polarity, the Peltier supply current flows through the Peltier element in a second direction, where the second direction is opposite the first direction, and the condensation body is heated; and
a discharge apparatus,
wherein the device is configured such that, when the device is positioned in an interior of a switch cabinet, moisture condensed on the condensation body is discharged from the interior of the switch cabinet to an exterior of the switch cabinet via the discharge apparatus, and
wherein the electronic control circuit is configured to temporarily change the polarity of the Peltier supply current from the first polarity to the second polarity.

17. The device according to claim 16, further comprising:
a heat sink,
wherein the heating side of the Peltier element is connected to the heat sink in a thermally conductive manner.

18. The device according to claim 17,
wherein the device is configured such that, when the device is positioned in the interior of the switch cabinet, the heat sink is arranged entirely in the interior of the switch cabinet without any connection to the exterior of the switch cabinet.

19. The device according to claim 17, further comprising:
a condensation body fan; and
a heat sink fan,
wherein the condensation body fan blows air through the condensation body, and
wherein the heat sink fan blows air through the heat sink.

20. The device according to claim 19,
wherein the condensation body fan blows air through the condensation body in a first flow direction, and
wherein the heat sink fan blows air through the heat sink in a second flow direction, where the second flow direction is opposite to the first flow direction.

21. The device according to claim 20, further comprising:
an air conduit apparatus,
wherein the air conduit apparatus conducts cold air leaving the condensation body to an air intake of the heat sink.

22. The device according to claim 17,
wherein the heat sink is larger than the condensation body.

23. The device according to claim 17,
wherein the heat sink fan has a larger input power than the condensation body fan.

24. The device according to claim 16,
wherein the electronic control circuit is configured to temporarily change the polarity of the Peltier supply from the first polarity to the second polarity upon detection of a freezing condition.

25. The device according to claim 24, further comprising:
a temperature sensor,
wherein the temperature sensor measures a temperature corresponding to a temperature of the condensation body and outputs a temperature sensor signal, and
wherein the electronic control circuit is configured to detect the freezing condition based on the temperature sensor signal.

26. The device according to claim 25,
wherein the electronic control circuit is configured to detect the freezing condition when the temperature corresponding to the temperature of the condensation body falls below a first predetermined temperature.

27. The device according to claim 26,
wherein the electronic control circuit is configured to temporarily change the polarity of the Peltier supply current from the first polarity to the second polarity only after a predetermined duration after the temperature corresponding to the temperature of the condensation body falls below the first predetermined temperature.

28. The device according to claim 27,
wherein the electronic control circuit is configured such that, after the electronic control circuit changes the polarity of the Peltier supply current from the first polarity to the second polarity, the electronic control circuit changes the polarity of the Peltier supply current back to the first direction upon detection of a defrosting condition.

29. The device according to claim 28,
wherein the defrosting condition is detected if the temperature corresponding to the temperature of the condensation body exceeds a second predetermined temperature.

30. The device according to claim 16, further comprising:
an air moisture sensor,
wherein the device is configured such that, when the device is positioned in the interior of the switch cabinet, the air moisture sensor measures an air moisture in the interior of the switch cabinet, and
wherein the electronic control circuit is configured to control the Peltier current supply based on an air moisture signal from the air moisture sensor.

31. The device according to claim 16, further comprising:
the direct current voltage source,
wherein the electronic control circuit is connected to the direct current voltage source.

32. The device according to claim 29, further comprising:
a heat sink,
wherein the heating side of the Peltier element is connected to the heat sink in a thermally conductive manner;
an air moisture sensor,
wherein the device is configured such that, when the device is positioned in the interior of the switch cabinet, the air moisture sensor measures an air moisture in the interior of the switch cabinet, and
wherein the electronic control circuit is configured to control the Peltier current supply based on an air moisture signal from the air moisture sensor;
a condensation body fan; and
a heat sink fan,
wherein the condensation body fan blows air through the condensation body, and
wherein the heat sink fan blows air through the heat sink.

33. The device according to claim 32, further comprising:
an air conduit apparatus,
wherein the condensation body fan blows air through the condensation body in a first flow direction,
wherein the heat sink fan blows air through the heat sink in a second flow direction, where the second flow direction is opposite to the first flow direction,
wherein the air conduit apparatus conducts cold air leaving the condensation body to an air intake of the heat sink, and
wherein the device is configured such that, when the device is positioned in the interior of the switch cabinet, the heat sink is arranged entirely in the interior of the switch cabinet without any connection to the exterior of the switch cabinet.

34. A method for removing moisture from a switch cabinet, comprising:
positioning a Peltier element and a condensation body in an interior of a switch cabinet,
wherein the Peltier element has a cooling side and a heating side;
connecting the cooling side of the Peltier element to the condensation body in a thermally conductive manner;
connecting the Peltier element to a direct current voltage source;
flowing a Peltier supply current through the Peltier element in a first direction so as to cool the condensation body;
discharging moisture condensed on the condensation body from the interior of the switch cabinet to an exterior of the switch cabinet; and
temporarily changing a polarity of the Peltier supply current such that the Peltier supply current flows through the Peltier element in a second direction that is opposite to the first direction.

35. A switch cabinet, comprising;
a device for removing moisture from a switch cabinet according to claim 16,
wherein the device for removing moisture from a switch cabinet is positioned in the interior of the switch cabinet.
